(19) United States
(12) Patent Application Publication
(10) Pub. No.: US 2025/0330141 A1
(43) Pub. Date: Oct. 23, 2025

(54) TEMPERATURE COMPENSATED SURFACE ACOUSTIC WAVE DEVICE WITH DIFFERENT TYPES OF RESONATORS

(71) Applicant: Skyworks Solutions, Inc., Irvine, CA (US)

(72) Inventors: Qiuyan Zhou, Newark, CA (US); Nan Wu, Irvine, CA (US); Yiliu Wang, Irvine, CA (US)

(21) Appl. No.: 19/176,707

(22) Filed: Apr. 11, 2025

Related U.S. Application Data
(60) Provisional application No. 63/637,507, filed on Apr. 23, 2024.
(60) Provisional application No. 63/637,520, filed on Apr. 23, 2024.

(51) Int. Cl. H03H 9/02; H03H 9/54; H03H 9/64

(52) U.S. Cl. CPC H03H 9/02834; H03H 9/02559; H03H 9/54; H03H 9/64

(57) ABSTRACT

A surface acoustic wave device and a method of forming the surface acoustic wave device are disclosed. The surface acoustic wave device can include a piezoelectric layer, a first resonator and a second resonator in electrical communication with the piezoelectric layer, a temperature compensation layer over the first resonator and the second resonator, and a passivation layer over the temperature compensation layer. The first resonator has a different resonator type from the second resonator. A first thickness of the passivation layer over the first resonator is different from a second thickness of the passivation layer over the second resonator.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/637,507, filed Apr. 23, 2024, titled “SHEAR HORIZONTAL MODE SPUR SUPPRESSION FOR TEMPERATURE COMPENSATED SURFACE ACOUSTIC WAVE DEVICES,” and U.S. Provisional Patent Application No. 63/637,520, filed Apr. 23, 2024, titled “TEMPERATURE COMPENSATED SURFACE ACOUSTIC WAVE DEVICE WITH DIFFERENT TYPES OF RESONATORS,” are hereby incorporated by reference under 37 CFR 1.57 in their entirety.

### BACKGROUND

### Field

Embodiments of this disclosure relate to surface acoustic wave (SAW) devices.

### Description of Related Technology

Acoustic wave filters can be implemented in radio frequency electronic apparatuses. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a surface acoustic wave device in which a Rayleigh mode is a main mode, the surface acoustic wave device including: a piezoelectric layer; a first resonator and a second resonator in electrical communication with the piezoelectric layer, the first resonator having a different resonator type from the second resonator; and a passivation layer having a first thickness over the first resonator and a second thickness over the second resonator, the first thickness being different from the second thickness.

In some embodiments, the techniques described herein relate to a surface acoustic wave device further including a temperature compensation layer between the piezoelectric layer and the passivation layer.

In some embodiments, the techniques described herein relate to a surface acoustic wave device wherein the temperature compensation layer has a thickness in a range between 0.15 L and 0.6 L where L is a wavelength a surface acoustic wave generated by the first resonator.

In some embodiments, the techniques described herein relate to a surface acoustic wave device wherein the temperature compensation layer has different thicknesses over the first resonator and the second resonator.

In some embodiments, the techniques described herein relate to a surface acoustic wave device wherein the piezoelectric layer includes lithium niobate.

In some embodiments, the techniques described herein relate to a surface acoustic wave device wherein the lithium niobate has a cut angle in a range between 118 degrees and 138 degrees.

In some embodiments, the techniques described herein relate to a surface acoustic wave device wherein the first resonator is a one-port resonator, and the second resonator is a multi-mode surface acoustic wave resonator.

In some embodiments, the techniques described herein relate to a surface acoustic wave device wherein the first thickness being greater than the second thickness.

In some embodiments, the techniques described herein relate to a surface acoustic wave device wherein the passivation layer has the first thickness over an active region of the one-port resonator.

In some embodiments, the techniques described herein relate to a surface acoustic wave device wherein the first thickness is at least 10% greater than the second thickness.

In some embodiments, the techniques described herein relate to a surface acoustic wave device wherein a difference between the first thickness and the second thickness is at least 2 nanometers.

In some embodiments, the techniques described herein relate to a surface acoustic wave device wherein a difference between the first thickness and the second thickness is at least 5 nanometers.

In some embodiments, the techniques described herein relate to a surface acoustic wave device wherein the difference between the first thickness and the second thickness is in a range between 10 nanometers and 100 nanometers.

In some aspects, the techniques described herein relate to a method of manufacturing a surface acoustic wave device, the method including: providing a piezoelectric layer having a first region and a second region; forming a first resonator in the first region and a second resonator in the second region, the first and second resonators generate a Rayleigh mode as a main mode; and forming a passivation layer having a first thickness over the first resonator and a second thickness over the second resonator, the first thickness being different from the second thickness.

In some embodiments, the techniques described herein relate to a method further including providing a temperature compensation layer between the passivation layer and the first and the second resonators.

In some embodiments, the techniques described herein relate to a method wherein forming the passivation layer includes providing a blanket passivation layer over the temperature compensation layer, and removing at least a portion of the blanket passivation layer over the second resonator such that the first thickness is greater than the second thickness.

In some embodiments, the techniques described herein relate to a method wherein a difference between the first thickness and the second thickness is at least 2 nanometers.

In some aspects, the techniques described herein relate to an acoustic wave filter for filtering a radio frequency signal, the acoustic wave filter including: a plurality of resonators in electrical communication with a piezoelectric layer, the plurality of resonators including a first resonator and a second resonator, the first resonator having a different resonator type from the second resonator, the first and second resonators generate a Rayleigh mode as a main mode; and a passivation layer having a first thickness over the first resonator and a second thickness over the second resonator, the first thickness being different from the second thickness.

In some embodiments, the techniques described herein relate to an acoustic wave filter wherein a difference between the first thickness and the second thickness is at least 2 nanometers.

In some embodiments, the techniques described herein relate to an acoustic wave filter wherein the difference between the first thickness and the second thickness is in a range between 10 nanometers and 100 nanometers.

In some aspects, the techniques described herein relate to a surface acoustic wave device including: a piezoelectric layer; a first resonator and a second resonator in electrical communication with the piezoelectric layer, the first resonator having a different resonator type from the second resonator; a temperature compensation layer over the first resonator and the second resonator; and a passivation layer over the temperature compensation layer, a first thickness of the passivation layer over the first resonator being different from a second thickness of the passivation layer over the second resonator.

In some embodiments, the techniques described herein relate to a surface acoustic wave device wherein the piezoelectric layer includes a lithium niobate layer.

In some embodiments, the techniques described herein relate to a surface acoustic wave device wherein the lithium niobate layer has a cut angle in a range between 118 degrees and 138 degrees.

In some embodiments, the techniques described herein relate to a surface acoustic wave device wherein the temperature compensation layer has a thickness in a range between 0.15 L and 0.6 L where L is a wavelength a surface acoustic wave generated by the first resonator.

In some embodiments, the techniques described herein relate to a surface acoustic wave device wherein the temperature compensation layer has different thicknesses over the first resonator and the second resonator.

In some embodiments, the techniques described herein relate to a surface acoustic wave device wherein the first resonator is a one-port resonator, and the second resonator is a multi-mode surface acoustic wave resonator.

In some embodiments, the techniques described herein relate to a surface acoustic wave device wherein the first thickness being greater than the second thickness.

In some embodiments, the techniques described herein relate to a surface acoustic wave device wherein the passivation layer has the first thickness over an active region of the one-port resonator.

In some embodiments, the techniques described herein relate to a surface acoustic wave device wherein the first thickness is at least 10% greater than the second thickness.

In some embodiments, the techniques described herein relate to a surface acoustic wave device wherein a difference between the first thickness and the second thickness is at least 2 nanometers.

In some embodiments, the techniques described herein relate to a surface acoustic wave device wherein a difference between the first thickness and the second thickness is at least 5 nanometers.

In some embodiments, the techniques described herein relate to a surface acoustic wave device wherein the difference between the first thickness and the second thickness is in a range between 10 nanometers and 100 nanometers.

In some aspects, the techniques described herein relate to a method of manufacturing a surface acoustic wave device, the method including: providing a piezoelectric layer; forming a first resonator and a second resonator in electrical communication with the piezoelectric layer, the first resonator having a different resonator type from the second resonator; forming a temperature compensation layer over the first resonator and the second resonator; and forming a passivation layer over the temperature compensation layer, a first thickness of the passivation layer over the first resonator being different from a second thickness of the passivation layer over the second resonator.

In some embodiments, the techniques described herein relate to a method wherein the piezoelectric layer includes a lithium niobate layer.

In some embodiments, the techniques described herein relate to a method wherein forming the passivation layer includes providing a blanket passivation layer over the temperature compensation layer, and removing at least a portion of the blanket passivation layer over the second resonator such that the first thickness is greater than the second thickness.

In some embodiments, the techniques described herein relate to a method wherein a difference between the first thickness and the second thickness is at least 2 nanometers.

In some embodiments, the techniques described herein relate to a method wherein forming the temperature compensation layer includes forming a trench in the temperature compensation layer.

In some aspects, the techniques described herein relate to an acoustic wave filter for filtering a radio frequency signal, the acoustic wave filter including: a plurality of resonators in electrical communication with a piezoelectric layer, the plurality of resonators including a first resonator and a second resonator, the first resonator having a different resonator type from the second resonator; a temperature compensation layer over the first resonator and the second resonator; and a passivation layer over the temperature compensation layer, a first thickness of the passivation layer over the first resonator being different from a second thickness of the passivation layer over the second resonator.

In some embodiments, the techniques described herein relate to an acoustic wave filter wherein a difference between the first thickness and the second thickness is at least 2 nanometers.

In some embodiments, the techniques described herein relate to an acoustic wave filter wherein the difference between the first thickness and the second thickness is in a range between 10 nanometers and 100 nanometers.

The present disclosure relates to U.S. Patent Application No.______ [Attorney Docket SKYWRKS.1534A1], titled “SHEAR HORIZONTAL MODE SPUR SUPPRESSION FOR TEMPERATURE COMPENSATED SURFACE ACOUSTIC WAVE DEVICES,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a schematic top plan view of an acoustic wave device according to an embodiment.

FIG. 1B is a schematic cross-sectional side view of the acoustic wave device of FIG. 1A.

FIG. 2A is a schematic top plan view of an acoustic wave device according to another embodiment.

FIG. 2B is a schematic cross-sectional side view of the acoustic wave device of FIG. 2A.

FIG. 3A is a schematic top plan view of an acoustic wave device according to another embodiment.

FIG. 3B is a schematic cross-sectional side view of the acoustic wave device of FIG. 3A.

FIG. 4A is a schematic top plan view of a portion of an acoustic wave device according to another embodiment.

FIG. 4B is a schematic cross-sectional side view of the portion of the acoustic wave device prior to creating a thickness difference.

FIG. 4C is a schematic cross-sectional side view of the portion of the acoustic wave device after creating the thickness difference.

FIGS. 5A-7B are graphs comparing compiling of mode (COM) simulation results and resonator test evaluation group (rTEG) measurements with finite element method (FEM) simulation results for one-port temperature compensated surface acoustic wave (TC-SAW) resonators having different piezoelectric layer cut angles (128.5°, 129.5°, and) 130.5°.

FIGS. 8A-8C are graphs comparing COM simulation results and rTEG measurements with FEM simulation results for double mode surface acoustic wave (DMS) resonators having different piezoelectric layer cut angles (128.5°, 129.5°, and) 130.5°.

FIGS. 9A-9D are graphs comparing COM simulation results and rTEG measurements with FEM simulation results for one-port temperature compensated surface acoustic wave (TC-SAW) resonators having different passivation layer thicknesses.

FIGS. 10A and 10B are graphs comparing COM simulation results and TEG measurements with FEM simulation results for double mode surface acoustic wave (DMS) resonators having different passivation layer thicknesses.

FIG. 11 is a graph showing filter test evaluation group (fTEG) measurement results of a temperature compensated surface acoustic wave (TC-SAW) resonator with a thinner passivation layer and a TC-SAW with a thicker passivation layer.

FIG. 12A is a schematic top plan view of an acoustic wave device according to an embodiment.

FIG. 12B is a schematic cross-sectional side view of the acoustic wave device of FIG. 12A.

FIG. 13A is a schematic diagram of a transmit filter that includes a surface acoustic wave resonator according to an embodiment.

FIG. 13B is a schematic diagram of a receive filter that includes a surface acoustic wave resonator according to an embodiment.

FIG. 14 is a schematic diagram of a radio frequency module that includes a surface acoustic wave resonator according to an embodiment.

FIG. 15 is a schematic diagram of a radio frequency module that includes filters with surface acoustic wave resonators according to an embodiment.

FIG. 16 is a schematic block diagram of a module that includes an antenna switch and duplexers that include a surface acoustic wave resonator according to an embodiment.

FIG. 17A is a schematic block diagram of a module that includes a power amplifier, a radio frequency switch, and duplexers that include a surface acoustic wave resonator according to an embodiment.

FIG. 17B is a schematic block diagram of a module that includes filters, a radio frequency switch, and a low noise amplifier according to an embodiment.

FIG. 18A is a schematic block diagram of a wireless communication device that includes a filter with a surface acoustic wave resonator in accordance with one or more embodiments.

FIG. 18B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Various features discussed herein can be implemented in any suitable SAW device such as a temperature compensated (TC) SAW device.

A shear horizontal (SH) spur in a surface acoustic wave (SAW) device refers to an undesired signal or artifact that arises due to the presence of SH waves. These spurious signals can interfere with the desired signal and degrade the performance of the SAW device. A cut angle of a piezoelectric layer can be adjusted to suppress the SH spur. However, a cut angle suitable for a first resonator having a first resonator type may be different from a cut angle suitable for a second resonator having a second resonator type. Also, various other factors can affect the optimal piezoelectric cut angle of a SAW device. For example, a thickness of a temperature compensation layer (e.g., silicon oxide layer) in a temperature compensated surface acoustic wave (TC-SAW) device can affect the optimal piezoelectric cut angle of the TC-SAW device. In some applications, the optimal piezoelectric cut angle of the TC-SAW device may be greater when the piezoelectric layer thickness is thicker. An ideal thickness of the temperature compensation layer over the first resonator may be different from an ideal thickness of the temperature compensation layer over the second resonator. Accordingly, it can be challenging to optimize a SAW device that includes two or more resonators having different resonator types to suppress the SH spurs.

Various embodiments disclosed herein relate to acoustic wave devices, such as filters, that include two or more resonators having different resonator types. The resonators can include temperature compensated surface acoustic wave (TC-SAW) resonators. The TC-SAW resonators can generate Rayleigh mode as the main mode. The acoustic wave devices disclosed herein can include structures that can suppress the SH mode spur(s).

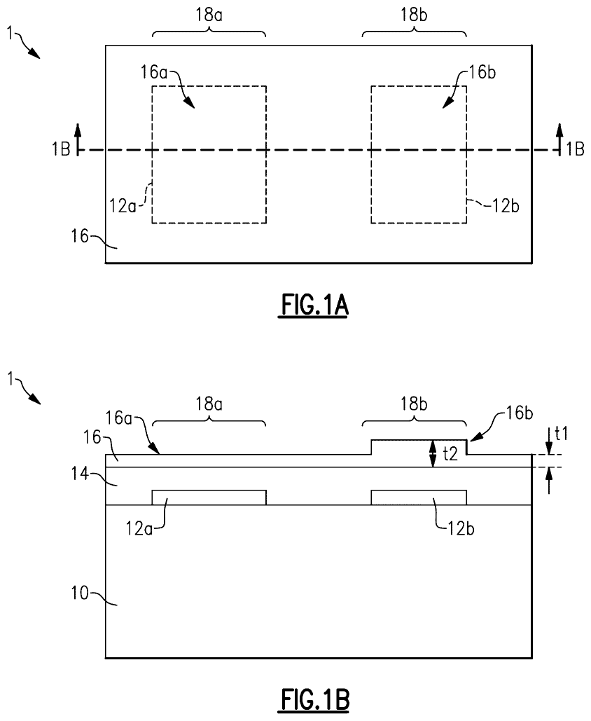

FIG. 1A is a schematic top plan view of an acoustic wave device 1 according to an embodiment. FIG. 1B is a schematic cross-sectional side view of the acoustic wave device 1 of FIG. 1A. The acoustic wave device 1 can be an acoustic wave filter for filtering a radio frequency signal. The acoustic wave device 1 can include a piezoelectric layer 10, a first resonator 12a, a second resonator 12b, a temperature compensation layer 14, and a passivation layer 16.

The piezoelectric layer 10 can include any suitable piezoelectric layer, such as a lithium based piezoelectric layer. In some embodiments, the piezoelectric layer 10 can be a lithium niobate (LN) layer. For example, the piezoelectric layer 10 can be an LN layer having a cut angle of about 118° (118° Y-cut X-propagation LN) or more or a cut angle of about 138° (138Y-cut X-propagation LN) or less. For example, the piezoelectric layer 10 can be 128±20° Y-cut LN, 128±15° Y-cut LN, 128±10° Y-cut LN, or 128±5° Y-cut LN. A thickness of the piezoelectric layer 10 can be selected based at least in part on a wavelength λ or L of a surface acoustic wave generated by the acoustic wave device 1 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 10 can be sufficiently thick to avoid significant frequency variation. In some embodiments, the piezoelectric layer 10 can include lithium tantalate (LT) and lithium niobate (LN). The acoustic wave resonator 1 can use Rayleigh waves as the main mode.

The first resonator 12a and the second resonator 12b have different resonator types. Therefore, the acoustic wave device 1 can be referred to as a hybrid structure or device. In some embodiments, the first resonator 12a or the second resonator 12b can be a one-port surface acoustic wave resonator or a multi-mode surface acoustic wave resonator. The multi-mode surface acoustic wave resonator can include interdigital transducer (IDT) electrodes that are longitudinally coupled with one another. A double mode SAW (DMS) resonator is an example of the multi-mode SAW resonator. In some embodiments, a plurality of one-port resonators can be arranged to form a ladder filter. For example, the first resonator 12a can be a DMS resonator and the second resonator 12b can be a one-port resonator. The first resonator 12a can be positioned in a first region 18a and the second resonator 12b can be positioned in a second region 18b.

The temperature compensation layer 14 can be a layer of any suitable material having a positive temperature coefficient of frequency. For instance, the temperature compensating layer can be a silicon oxide layer (e.g., a silicon dioxide (SiO₂) layer), a tellurium oxide layer (e.g., a tellurium dioxide (TeO₂) layer), or a silicon oxyfluoride (SiOF) layer in certain applications. A temperature compensating layer can include any suitable combination of SiO₂, TeO₂, and/or SiOF. A thickness of the temperature compensation layer 14 can be adjusted to provide optimal temperature compensation for a resonator (e.g., the first resonator 12a and/or the second resonator 12b). For example, the coupling coefficient kt2 can be improved by the temperature compensation layer 14. In some embodiments, a thickness of the temperature compensation layer 14 in the first region 18a can be different from a thickness of the temperature compensation layer 14 in the second region 18b. In some embodiments, the temperature compensation layer 14 can have a thickness in a range between 0.15 L and 0.6 L where L is a wavelength a surface acoustic wave generated by the first resonator.

The passivation layer 16 can include any suitable material to increase the magnitude of the velocity of the wave traveling in the underlying region. According to some applications, the passivation layer 16 can include silicon nitride (SiN). In some embodiments, the passivation layer 16 can be patterned such that the acoustic propagation velocity can be adjusted at certain regions. In some instances, the passivation layer 16 can physically protect the first resonator 12a and the second resonator 12b. In some instances, the passivation layer 16 can be used for frequency trimming and/or frequency tuning. Therefore, the passivation layer 16 can also be referred to as a frequency trimming layer. The passivation layer 16 can include a silicon nitride (SiN) layer and/or an aluminum oxide (Al₂O₃) layer.

The passivation layer 16 has a first portion 16a in the first region 18a and a second portion 16b in the second region 18b. The first portion 16a can overlap the first resonator 12a and the second portion 16b can overlap the second resonator 12b. The first portion 16a has a first thickness t1 and the second portion has a second thickness t2. The first thickness t1 and the second thickness t2 are different. In some embodiments, the first thickness t1 and the second thickness t2 can be in a range between 0.05 L and 0.2 L, 0.075 L and 0.2 L, or 0.05 L and 0.1 L. In some embodiments, a difference between the first thickness t1 and the second thickness t2 can be in a range between 2 nanometers (nm) and 150 nm, 2 nm and 100 nm, 5 nm and 100 nm, 10 nm and 100 nm, or 5 nm and 50 nm. In some embodiments, the second thickness t2 can be at least 10%, 20%, 50%, or 75% greater than the first thickness t1.

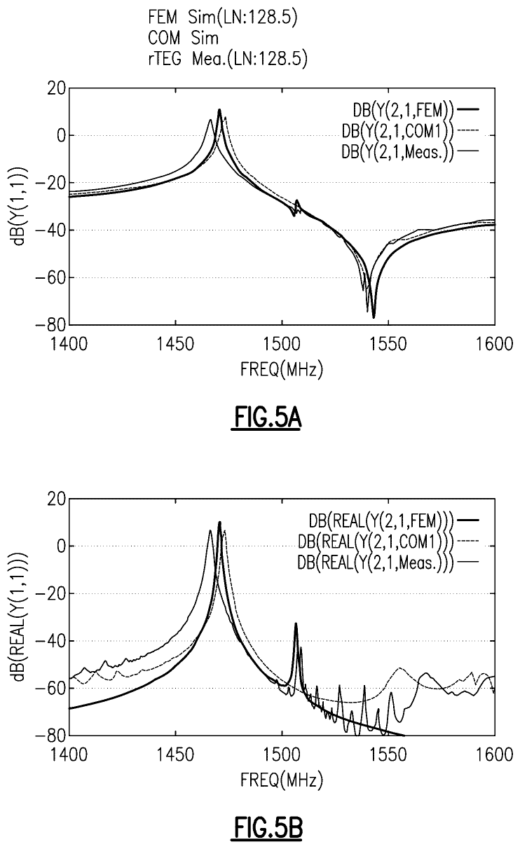

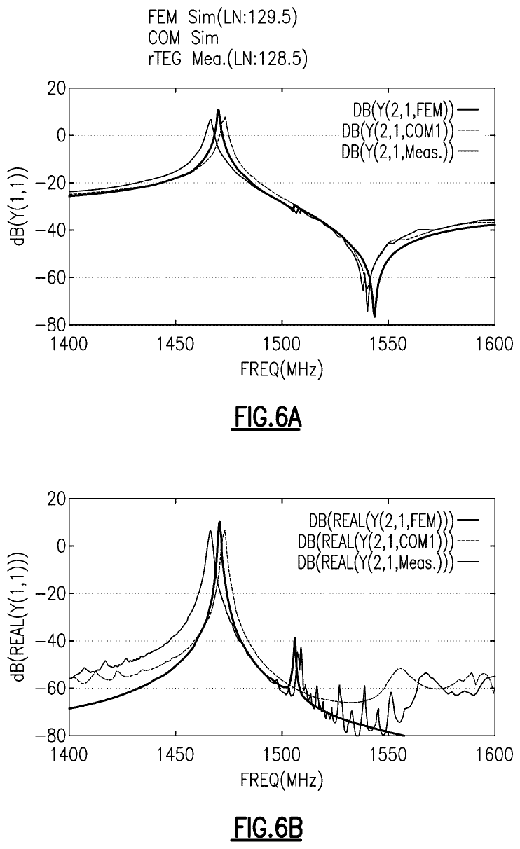

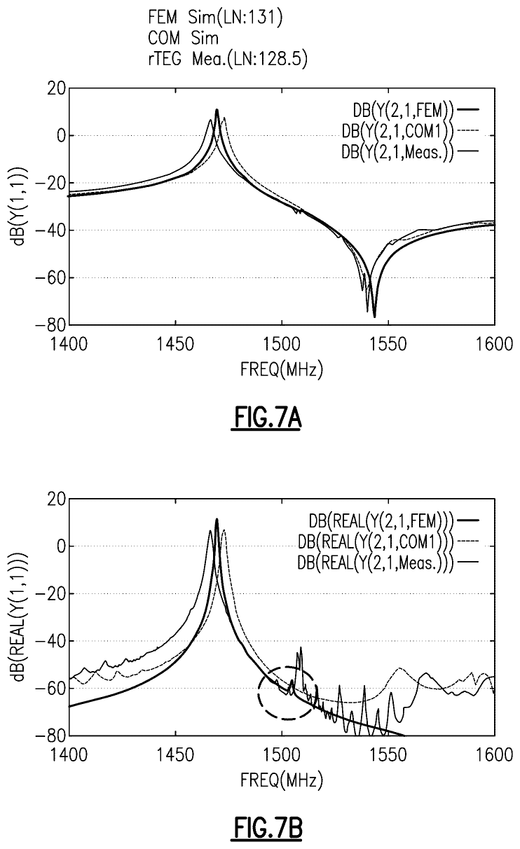

As described with respect to FIGS. 5A-12, the difference between the first thickness t1 and the second thickness t2 can contribute to suppressing the SH mode spur. A piezoelectric layer cut angle suitable for the first resonator 12a and a piezoelectric layer cut angle suitable for the second resonator 12b can be different. Therefore, when the first resonator 12a and the second resonator 12b are formed with the same piezoelectric layer 10, and the piezoelectric layer cut angle is selected for, for example, the first resonator 12a, there may be SH mode spur from the second resonator 12b. The thickness t2 of the second portion over the second resonator 12b can be adjusted to suppress the SH mode spur. Further, the thickness of the temperature compensation layer 14 can also be adjusted to provide a desired operation of the first resonator 12a and the second resonator 12b.

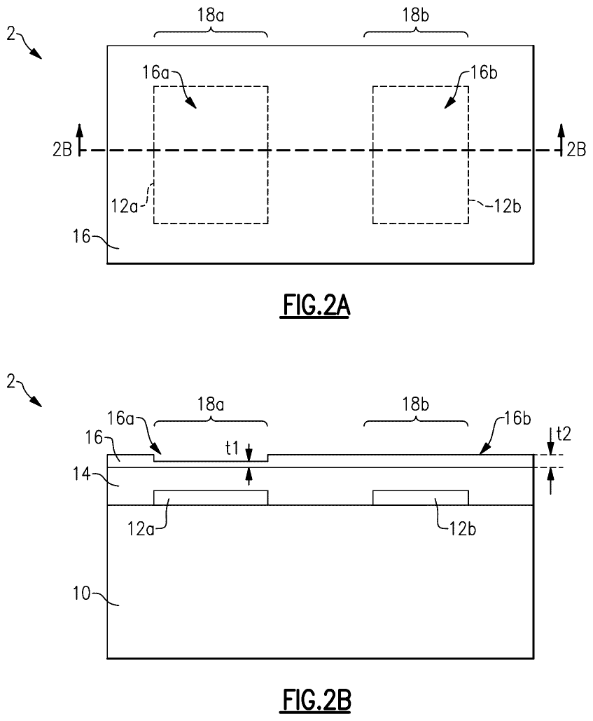

FIG. 2A is a schematic top plan view of an acoustic wave device 2 according to an embodiment. FIG. 2B is a schematic cross-sectional side view of the acoustic wave device 2 of FIG. 2A. Unless otherwise noted, the components of the acoustic wave device 2 shown in FIGS. 2A and 2B may be structurally and/or functionally the same as or generally similar to like components disclosed herein. The passivation layer 16 can predominantly have a thinner thickness as shown in FIGS. 1A and 1B, or predominantly have a thicker thickness as shown in FIGS. 2A and 2B.

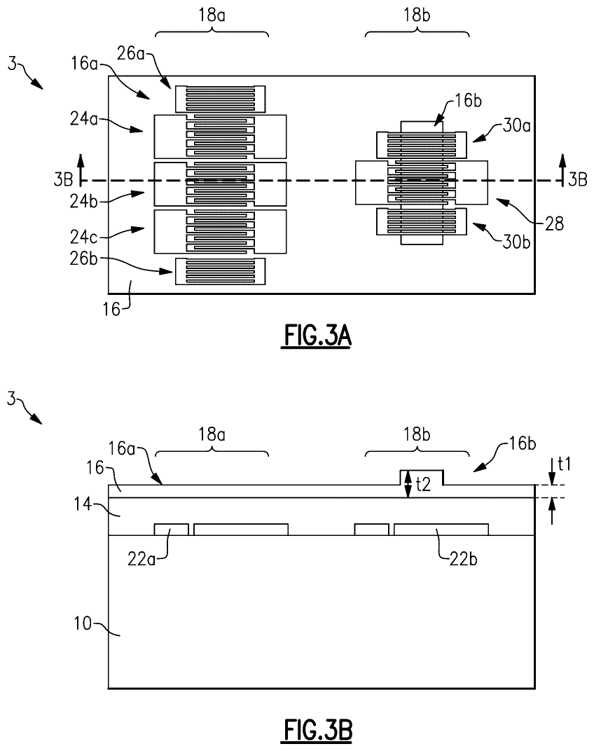

FIG. 3A is a schematic top plan view of an acoustic wave device 3 according to an embodiment. FIG. 3B is a schematic cross-sectional side view of the acoustic wave device 3 of FIG. 3A. Unless otherwise noted, the components of the acoustic wave device 3 shown in FIGS. 3A and 3B may be structurally and/or functionally the same as or generally similar to like components disclosed herein. The acoustic wave device 3 can be an acoustic wave filter for filtering a radio frequency signal. The acoustic wave device 3 can include a piezoelectric layer 10, a first resonator 22a, a second resonator 22b, a temperature compensation layer 14, and a passivation layer 16.

The first resonator 22a can be a DMS resonator and the second resonator 22b can be a one-port resonator. The first resonator 22a can include a first interdigital transducer (IDT) electrode 24a, a second IDT electrode 24b, a third IDT electrode 24c, and a pair of reflectors 26a, 26b that are longitudinally coupled along a wave propagation direction of the first resonator 22a. The second resonator 22b can include an IDT electrode 28 and a pair of reflectors 30a, 30b. The IDT electrode 28 is positioned between the pair pf reflectors 30a, 30b.

The IDT electrodes (e.g., the first to third IDT electrodes 24a-24c and the IDT electrode 28) can include any suitable IDT electrode material. For example, the IDT electrodes can include molybdenum (Mo), aluminum (Al), copper (Cu), Magnesium (Mg), titanium (Ti), tungsten (W), the like, or any suitable combination thereof. The IDT electrodes can have a multilayer structure that includes a first layer and a second layer. One of the first layer and the second layer can be more electrically conductive than the other, and the other one can be more durable (e.g., resistive to metal fatigue). In some embodiments, the first layer or the second layer can have a higher mass density and/or higher Young's modulus than the other. The interdigital transducer electrodes can be formed with (e.g., formed on or at least partially in) the piezoelectric layer 10. The piezoelectric layer 10 and the interdigital transducer electrodes can be provided in any suitable manner. For example, the piezoelectric layer 10 and the interdigital transducer electrodes can be provided in sequence. When the interdigital transducer electrodes are provided at least partially in the piezoelectric layer 10, the piezoelectric layer 10 can be partially etched and/or provided in a plurality of steps.

The IDT electrode 28 can include a first bus bar, a first set of fingers extending from the first bus bar, a second bus bar, and a second set of fingers extending from the second bus bar. The IDT electrode 28 includes a first gap region between the first set of fingers and the second bus bar and a second gap region between the second set of fingers and the first bus bar. The IDT electrode 28 can include an active region between the first and second gap regions. The active region can include a center region, a first border region between the center region and the first gap region, and a second border region between the center region and the second gap region.

The passivation layer 16 has a first portion 16a in the first region 18a and a second portion 16b in the second region 18b. The first portion 16a can at least partially overlap the first resonator 22a and the second portion 16b can at least partially overlap the second resonator 22b. The location of the second portion 16b can contribute to suppressing the SH mode spur from the second resonator 22b. In some embodiments, the second portion 16b can at least overlap the center region of the IDT electrode 28.

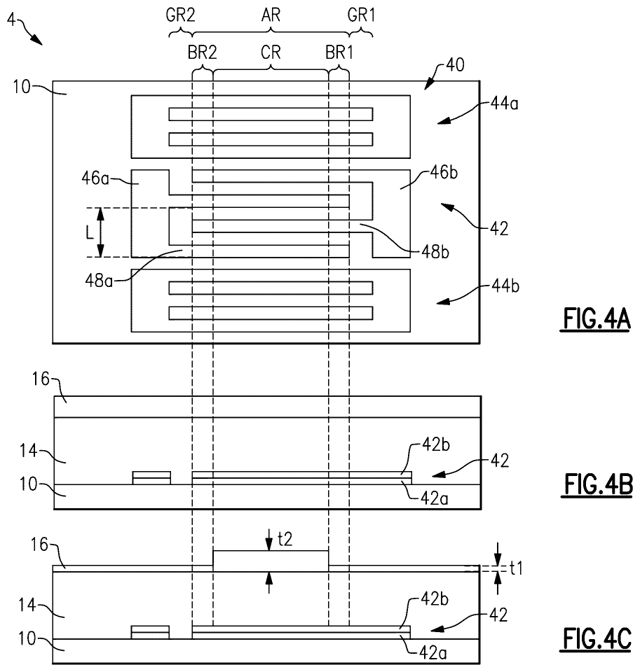

FIG. 4A is a schematic top plan view of a portion of an acoustic wave device 4 according to an embodiment. The acoustic wave device 4 can include two or more resonators with different resonator types but only a resonator 40 is illustrated in FIG. 4A. FIG. 4B is a schematic cross-sectional side view of the portion of the acoustic wave device 4 prior to creating a thickness difference in a passivation layer 16. FIG. 4C is a schematic cross-sectional side view of the portion of the acoustic wave device 4 after creating the thickness difference. Unless otherwise noted, the components of the acoustic wave device 4 shown in FIGS. 4A, 4B, and 4C may be structurally and/or functionally the same as or generally similar to like components disclosed herein. The acoustic wave device 4 can be an acoustic wave filter for filtering a radio frequency signal. The acoustic wave device 4 can include a piezoelectric layer 10, the resonator 40, a temperature compensation layer 14, and the passivation layer 16.

The resonator 40 includes an IDT electrode 42 and a pair of reflectors 44a, 44b. The IDT electrode 42 can include a first bus bar 46a, a first set of fingers 48a extending from the first bus bar 46a, a second bus bar 46b, and a second set of fingers 48b extending from the second bus bar 46b. The IDT electrode 42 includes a first gap region GR1 between the first set of fingers 48a and the second bus bar 46b, and a second gap region GR2 between the second set of fingers 48b and the first bus bar 46a. The IDT electrode 42 can include an active region AR between the first and second gap regions GR1, GR2. The active region AR can include a center region CR, a first border region BR1 between the center region CR and the first gap region GR1, and a second border region BR2 between the center region CR and the second gap region GR2. The first and second border regions BR1, BR2 can be regions within 0.5 L, 1 L, or 1.5 L of the first and second sets of fingers 48a, 48b from respective edges of the first and second sets of fingers 48a, 48b or from the respective first or second gap regions GR1, GR2.

The IDT electrode 42 can have a multi-layer structure that includes a first layer 42a and a second layer 42b. The first layer 42a of the IDT electrode 42 can be referred to as a lower electrode layer. The first layer 42a of the IDT electrode 42 is disposed between the second layer 42b of the IDT electrode 42 and the piezoelectric layer 10. As illustrated, the first layer 42a of the IDT electrode 42 can have a first side in physical contact with the piezoelectric layer 10 and a second side in physical contact with the second layer 42b of the IDT electrode 42. The second layer 42b of the IDT electrode 42 can be referred to as an upper electrode layer. The second layer 42b of the IDT electrode 42 can be disposed over the first layer 42a of the IDT electrode 42. As illustrated, the second layer 42b of the IDT electrode 42 can have a first side in physical contact with the first layer 42a of the IDT electrode 42. In some other embodiments, the first layer 42a and the second layer 42b can be switched.

The passivation layer 16 has a first thickness t1 over non-center regions including the border regions BR1, BR2, the gap regions GR1, GR2, bus bars 46a, 46b, and regions outside of the resonator 40, and a second thickness t2 over the center region CR. The first thickness t1 and the second thickness t2 are different. In some embodiments, the first thickness t1 and the second thickness t2 can be in a range between 0.05 L and 0.2 L, 0.075 L and 0.2 L, or 0.05 L and 0.1 L. In some embodiments, a difference between the first thickness t1 and the second thickness t2 can be in a range between 2 nm and 150 nm, 2 nm and 100 nm, 5 nm and 100 nm, 10 nm and 100 nm, or 5 nm and 50 nm. In some embodiments, the second thickness t2 can be at least 10%, 20%, 50%, or 75% greater than the first thickness t1.

In FIG. 4B, a passivation layer 16 has a generally uniform thickness over the temperature compensation layer 14. A method of forming or creating the thickness difference between the first thickness t1 and the second thickness t2 can include providing a mask layer over the passivation layer 16 (e.g., a blanket passivation layer) and etching at least a portion of the passivation layer 16 to remove the portion of the passivation layer 16. In the illustrated example, the mask can be provided over the center region CR and the portions of the passivation layer 16 that are not covered by the mask can be removed (e.g., etched). The thinned portions of the passivation layer 16 can have the first thickness t1 that is thinner than the second thickness t2 which can be the original thickness of the passivation layer 16, in some embodiments. In some embodiments, forming the temperature compensation layer 14 can include forming a trench in the temperature compensation layer 14.

FIGS. 5A-11 will describe how the piezoelectric layer cut angle affects the SH mode spur and how the difference between the first thickness t1 and the second thickness t2 can contribute to suppressing the SH mode spur to provide an improved hybrid surface acoustic wave device that includes two or more different types of resonators.

FIGS. 5A-7B are graphs comparing compiling of mode (COM) simulation results and resonator test evaluation group (rTEG) measurements with finite element method (FEM) simulation results for one-port temperature compensated surface acoustic wave (TC-SAW) resonators having different piezoelectric layer cut angles (128.5°, 129.5°, and 130.5°). The TC-SAW resonators include a lithium niobate layer as the piezoelectric layer, and no passivation layer is provided. FIGS. 5A-7B indicate that, in a one-port TC-SAW resonator, the SH mode spur can be suppressed when the LN cut angle is increased (e.g., from 128.5° to 130.5°).

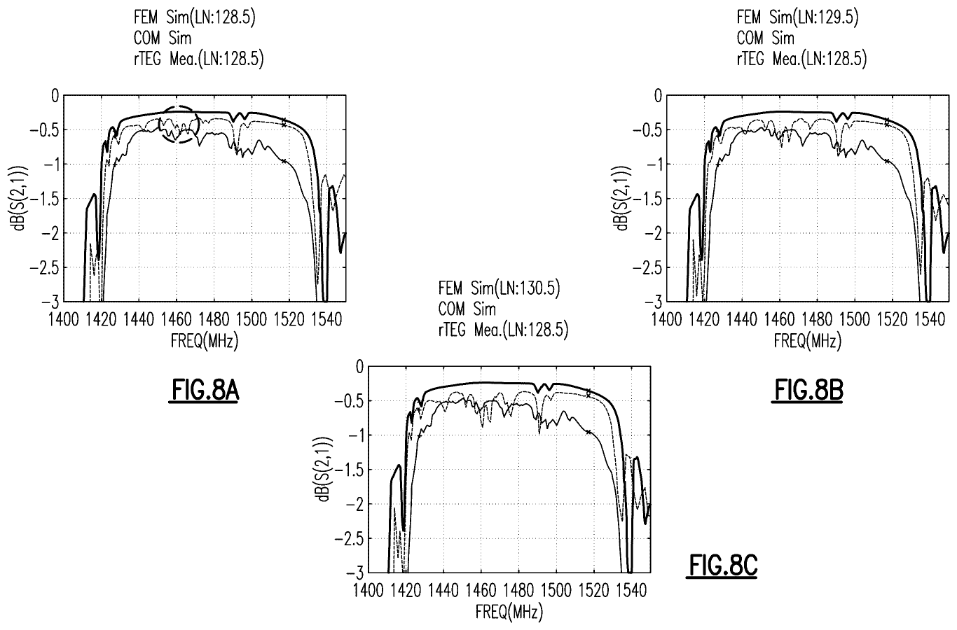

FIGS. 8A-8C are graphs comparing COM simulation results and rTEG measurements with FEM simulation results for double mode surface acoustic wave (DMS) resonators having different piezoelectric layer cut angles (128.5°, 129.5°, and 130.5°). The DMS resonators include a lithium niobate layer as the piezoelectric layer, and no passivation layer is provided. FIGS. 8A-8C indicate that, in a DMS resonator, the SH mode spur can be suppressed when the LN cut angle is decreased (e.g., from 130.5° to 128.5°).

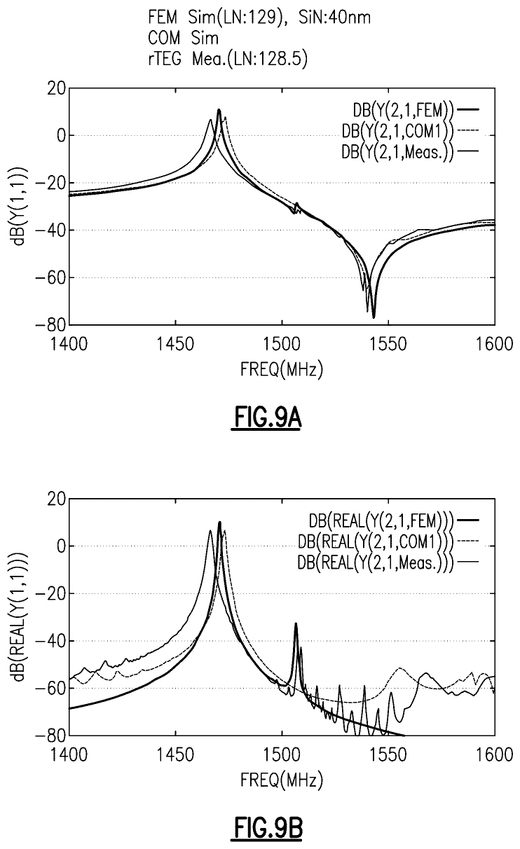

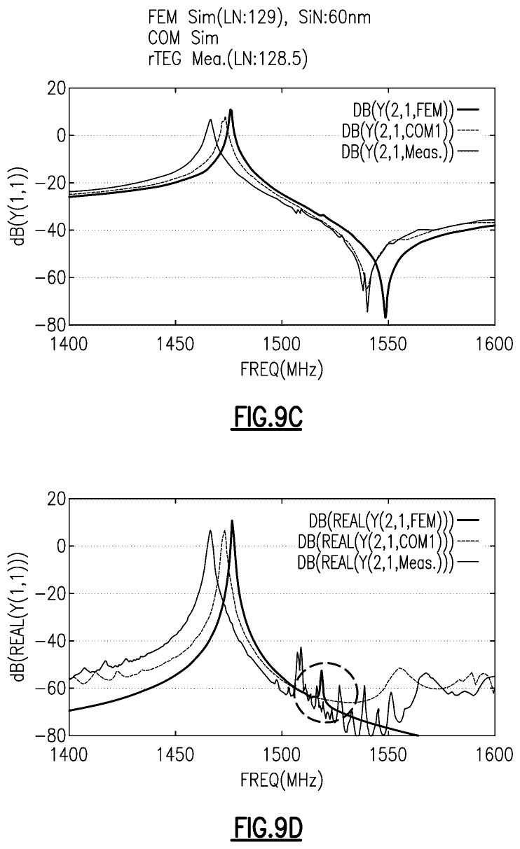

FIGS. 9A-9D are graphs comparing COM simulation results and rTEG measurements with FEM simulation results for one-port temperature compensated surface acoustic wave (TC-SAW) resonators having different passivation layer thicknesses. The TC-SAW resonators include a silicon nitride (SiN) layer as the passivation layer. In FIGS. 9A and 9B the thickness of the SiN layer is set to 40 nm. In FIGS. 9C and 9D the thickness of the SiN layer is set to 60 nm. FIGS. 10A and 10B are graphs comparing COM simulation results and rTEG measurements with FEM simulation results for double mode surface acoustic wave (DMS) resonators having different passivation layer thicknesses. The DMS resonators include a silicon nitride (SiN) layer as the passivation layer. In FIG. 10A the thickness of the SiN layer is set to 40 nm. In FIG. 10B the thickness of the SiN layer is set to 60 nm.

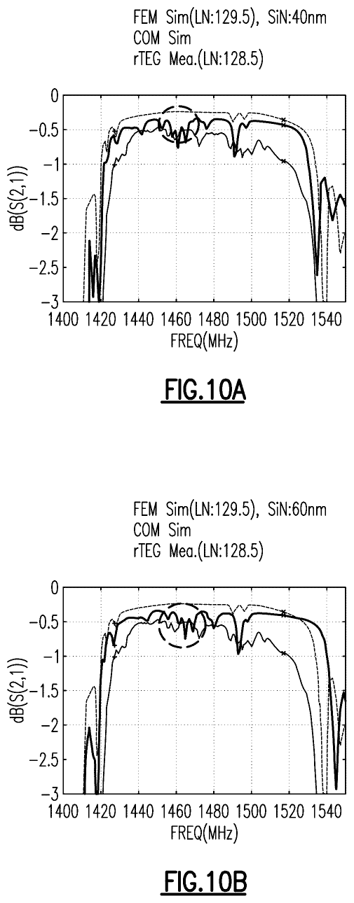

FIG. 11 is a graph showing filter test evaluation group (fTEG) measurement results of a temperature compensated surface acoustic wave (TC-SAW) resonator with a thinner passivation layer and a TC-SAW with a thicker passivation layer. FIG. 11 indicates that the thicker passivation layer can reduce the SH spur. In some embodiments, a thickness increase of at least 5 nm, at least 10 nm, or at least 15 nm can reduce the SH spur. For example, a passivation layer can have a thickness in a range of 50 nm to 60 nm to reduce the SH spur.

FIGS. 9A-11 indicate that increasing the SiN thickness can reduce the SH spurs. The SiN thickness may impact the SH spur less in the DMS resonator as compared to the one-port resonator. In some embodiments, the thickness of the passivation layer (e.g., the SiN layer) can be adjusted to suppress the SH mode spur. In some applications, it can be less preferred to have a significantly thick passivation layer as the frequency sensitivity can be low, which can impact yield in manufacturing the acoustic wave device, especially in a mass production. In various embodiments, a temperature compensated surface acoustic wave (TC-SAW) device that includes two or more resonators (e.g., a first resonator and a second resonator) of different types can have the piezoelectric layer cut angle more preferred for the first resonator. The TC-SAW device can include a passivation layer (SiN) layer that has a first thickness over the first resonator and a second thickness over the second resonator. The thicknesses may not be significantly thick for manufacturability. For example, the first and second thicknesses can be less than about 62.77 nm.

Any suitable principles and advantages disclosed herein can be implemented in a surface acoustic wave device having additional features such as a mini-bus bar, a piston mode structure (e.g., a metal strip, a finger nail, a hammer head, etc.). Although at least some of the illustrated embodiments disclosed herein include two resonators having different types, any suitable principles and advantages disclosed herein can be implemented in a surface acoustic wave device having three or more resonators having different types. In some embodiments, a temperature compensation layer can have different thicknesses at different regions.

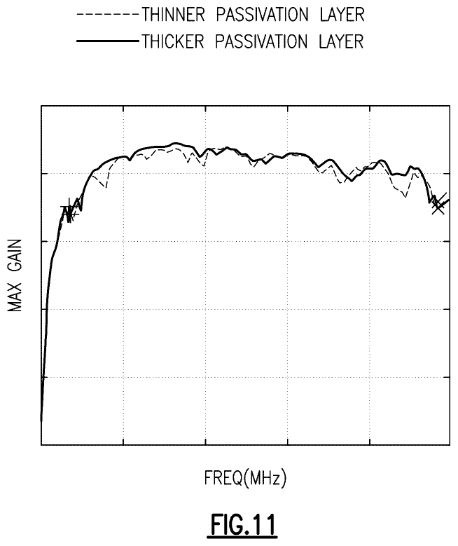

FIG. 12A is a schematic top plan view of an acoustic wave device 5 according to an embodiment. FIG. 12B is a schematic cross-sectional side view of the acoustic wave device 5 of FIG. 12A. Unless otherwise noted, the components of the acoustic wave device 5 shown in FIGS. 12A and 12B may be structurally and/or functionally the same as or generally similar to like components disclosed herein. The acoustic wave device 5 is generally similar to the acoustic wave device 1 of FIGS. 1A and 1B. In the acoustic wave device 5, the temperature compensation layer 14 has a recessed portion 14a. The recessed portion 14a can make a thickness of the temperature compensation layer 14 over the second resonator 12b thinner than a thickness of the temperature compensation layer 14 over the first resonator 12a. a portion (e.g., the second portion 16b) of the passivation layer 16 can be disposed in the recessed portion 14a. When the recessed portion 14a has a depth that corresponds to the thickness difference between the first and thicknesses t1, t2 of the passivation layer 16, a top surface of the passivation layer 16 can have a flat surface. Both the recessed portion 14a and the thickness difference between the first and thicknesses t1, t2 can contribute to improving the performance (e.g., reducing SH spur, improving coupling coefficient kt2, etc.) of the acoustic wave device 5.

Although FIGS. 12A and 12B illustrate that the recessed portion 14a is located between the second resonator 12b and the second portion 16b of the passivation layer 16 such that the thickness of the temperature compensation layer 14 is thinner therebetween, the temperature compensation layer 14 can have different thicknesses at any suitable locations. For example, the thickness of the temperature compensation layer 14 can be thinner over the first resonator 12a.

Acoustic wave devices disclosed herein can be formed or manufactured in any suitable manner. For example, a method of forming a surface acoustic wave device can include providing a piezoelectric layer having a first region and a second region. The method can include forming a first resonator in the first region and a second resonator in the second region. The method can include providing a temperature compensation layer over the first resonator and the second resonator. The method can include providing a passivation layer over the temperature compensation layer. The method can include removing at least a portion of the passivation layer over the first resonator such that a first thickness of the passivation layer is different from a second thickness of the passivation layer over the second resonator. In some embodiments, providing the temperature compensation layer can include removing (e.g., etching) a portion of the temperature compensation layer to form a recessed portion. In some embodiments, removing at least the portion of the passivation layer over the first resonator can include removing (e.g., etching) the portion of the passivation layer.

An acoustic wave device (e.g., a SAW device) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more conductive structures disclosed herein. FR1 can be from 410 MHz to 7.125 GHz, for example, as specified in a current 5G NR specification. One or more acoustic wave devices in accordance with any suitable principles and advantages disclosed herein can be included in a filter arranged to filter a radio frequency signal in a 4G LTE operating band and/or in a filter having a passband that includes a 4G LTE operating band and a 5G NR operating band.

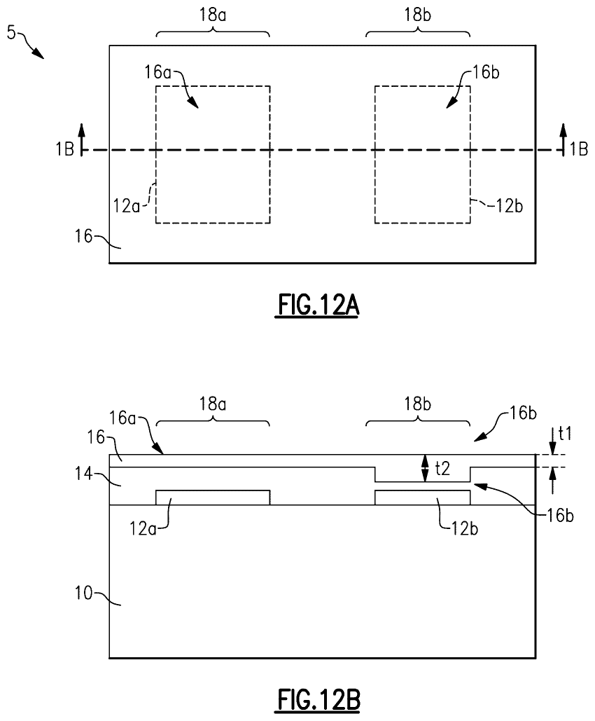

FIG. 13A is a schematic diagram of an example transmit filter 100 that includes surface acoustic wave devices according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be SAW devices in accordance with any suitable principles and advantages disclosed herein. For instance, one or more of the SAW resonators of the transmit filter 100 can be coupled by way of a conductive structure disclosed herein. Any suitable number of series SAW resonators and shunt SAW resonators can be included in a transmit filter 100.

FIG. 13B is a schematic diagram of a receive filter 105 that includes surface acoustic wave devices according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. Any suitable number of series SAW resonators and shunt SAW resonators can be included in a receive filter 105.

Although FIGS. 13A and 13B illustrate example ladder filter topologies, any suitable filter topology can include a conductive structure in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

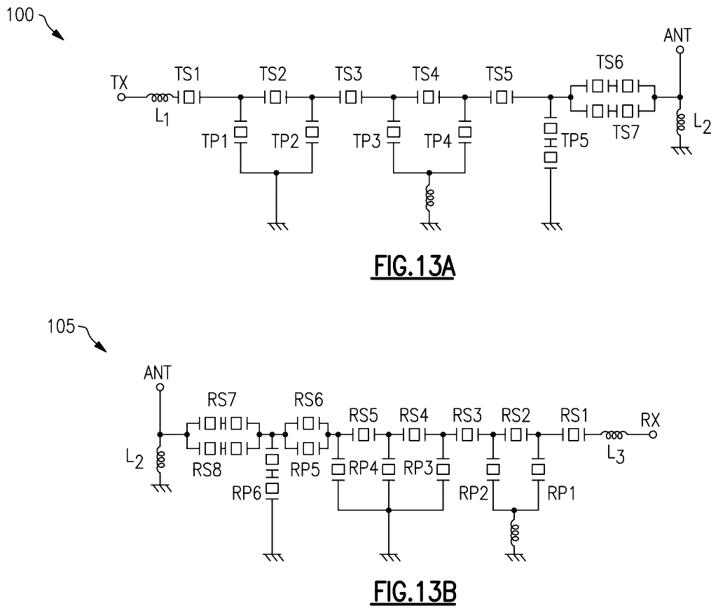

FIG. 14 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 14 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 14. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

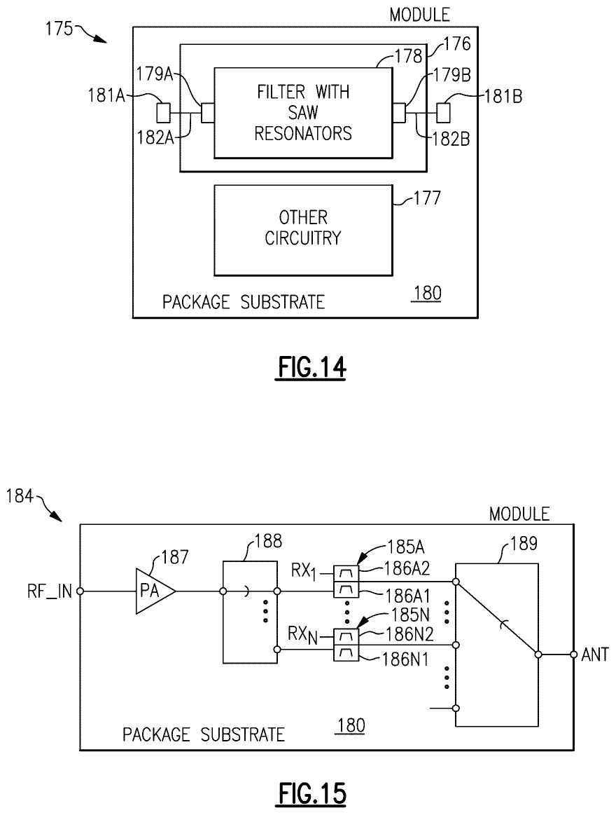

FIG. 15 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 15 illustrates duplexers, any suitable principles and advantages disclosed herein can be implemented in other multiplexers (e.g., quadplexers, hexaplexers, octoplexers, etc.) and/or in switch-plexers and/or standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

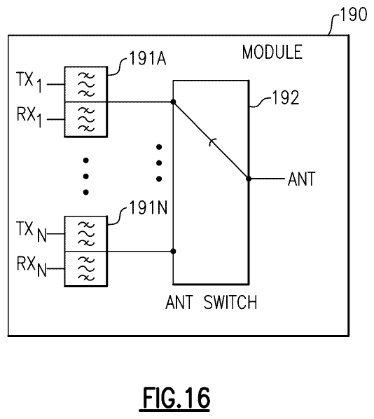

FIG. 16 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

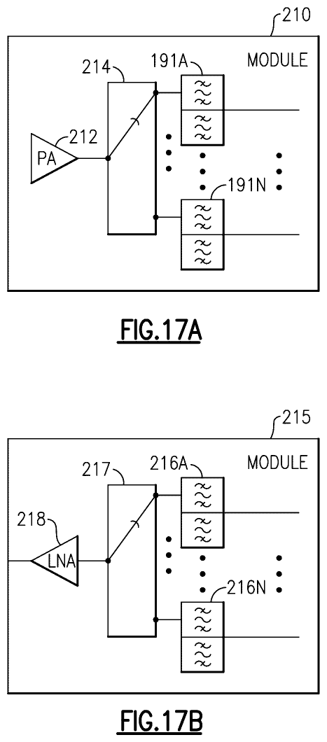

FIG. 17A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 17B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

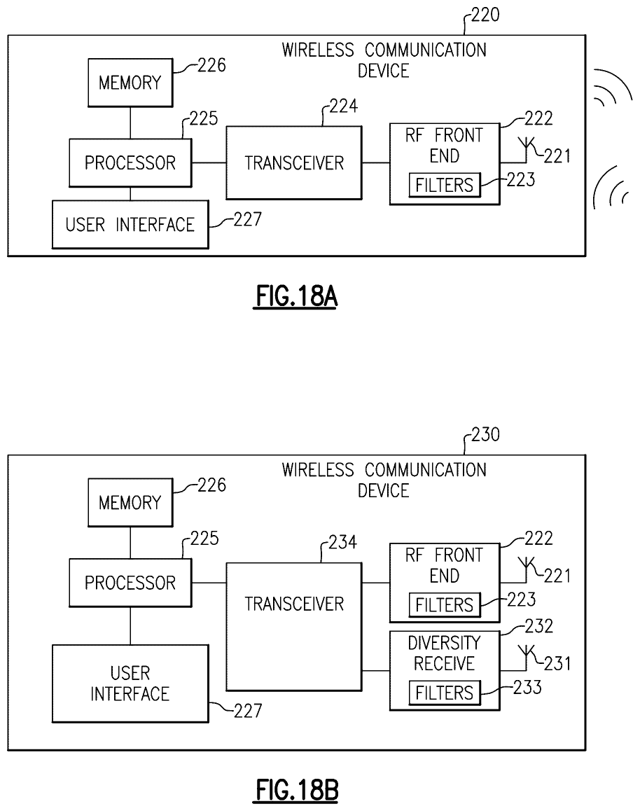

FIG. 18A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 18B is a schematic diagram of a wireless communication device 230 that includes filters 223 in a radio frequency front end 222 and a second filter 233 in a diversity receive module 232. The wireless communication device 230 is like the wireless communication device 220 of FIG. 18A, except that the wireless communication device 230 also includes diversity receive features. As illustrated in FIG. 18B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHZ, such as in a frequency range from about 450 MHz to 8.5 GHZ. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave device comprising:
a piezoelectric layer;
a first resonator and a second resonator in electrical communication with the piezoelectric layer, the first resonator having a different resonator type from the second resonator;
a temperature compensation layer over the first resonator and the second resonator; and
a passivation layer over the temperature compensation layer, a first thickness of the passivation layer over the first resonator being different from a second thickness of the passivation layer over the second resonator.

2. The surface acoustic wave device of claim 1 wherein the piezoelectric layer includes a lithium niobate layer.

3. The surface acoustic wave device of claim 2 wherein the lithium niobate layer has a cut angle in a range between 118 degrees and 138 degrees.

4. The surface acoustic wave device of claim 1 wherein the temperature compensation layer has a thickness in a range between 0.15 L and 0.6 L where L is a wavelength a surface acoustic wave generated by the first resonator.

5. The surface acoustic wave device of claim 4 wherein the temperature compensation layer has different thicknesses over the first resonator and the second resonator.

6. The surface acoustic wave device of claim 1 wherein the first resonator is a one-port resonator, and the second resonator is a multi-mode surface acoustic wave resonator.

7. The surface acoustic wave device of claim 6 wherein the first thickness being greater than the second thickness.

8. The surface acoustic wave device of claim 7 wherein the passivation layer has the first thickness over an active region of the one-port resonator.

9. The surface acoustic wave device of claim 7 wherein the first thickness is at least 10% greater than the second thickness.

10. The surface acoustic wave device of claim 1 wherein a difference between the first thickness and the second thickness is at least 2 nanometers.

11. The surface acoustic wave device of claim 1 wherein a difference between the first thickness and the second thickness is at least 5 nanometers.

12. The surface acoustic wave device of claim 11 wherein the difference between the first thickness and the second thickness is in a range between 10 nanometers and 100 nanometers.

13. A method of manufacturing a surface acoustic wave device, the method comprising:
providing a piezoelectric layer;
forming a first resonator and a second resonator in electrical communication with the piezoelectric layer, the first resonator having a different resonator type from the second resonator;
forming a temperature compensation layer over the first resonator and the second resonator; and
forming a passivation layer over the temperature compensation layer, a first thickness of the passivation layer over the first resonator being different from a second thickness of the passivation layer over the second resonator.

14. The method of claim 13 wherein the piezoelectric layer includes a lithium niobate layer.

15. The method of claim 13 wherein forming the passivation layer includes providing a blanket passivation layer over the temperature compensation layer, and removing at least a portion of the blanket passivation layer over the second resonator such that the first thickness is greater than the second thickness.

16. The method of claim 13 wherein a difference between the first thickness and the second thickness is at least 2 nanometers.

17. The method of claim 13 wherein forming the temperature compensation layer includes forming a trench in the temperature compensation layer.

18. An acoustic wave filter for filtering a radio frequency signal, the acoustic wave filter comprising:
a plurality of resonators in electrical communication with a piezoelectric layer, the plurality of resonators including a first resonator and a second resonator, the first resonator having a different resonator type from the second resonator;
a temperature compensation layer over the first resonator and the second resonator; and
a passivation layer over the temperature compensation layer, a first thickness of the passivation layer over the first resonator being different from a second thickness of the passivation layer over the second resonator.

19. The acoustic wave filter of claim 18 wherein a difference between the first thickness and the second thickness is at least 2 nanometers.

20. The acoustic wave filter of claim 19 wherein the difference between the first thickness and the second thickness is in a range between 10 nanometers and 100 nanometers.
